(19) United States
(12) Patent Application Publication
(10) Pub. No.: US 2025/0312887 A1
(43) Pub. Date: Oct. 9, 2025

(54) AUTOMATIC POLISHING PAD REPLACEMENT DEVICE AND POLISHING DEVICE INCLUDING THE SAME

(71) Applicant: SAMSUNG ELECTRONICS CO., LTD., Suwon-si (KR)

(72) Inventors: Youngtaek Kim, Suwon-si (KR); Sung Yong Park, Suwon-si (KR); Hyunshik Joo, Suwon-si (KR); Jubong Lee, Suwon-si (KR); Hoseop Choi, Suwon-si (KR)

(21) Appl. No.: 18/883,835

(22) Filed: Sep. 12, 2024

(30) Foreign Application Priority Data
Apr. 4, 2024 (KR) 10-2024-0046250

(51) Int. Cl. B24B 37/34; B24B 37/20

(52) U.S. Cl. CPC B24B 37/34; B24B 37/20

(57) ABSTRACT

An automatic polishing pad replacement device includes a foldable support that supports a polishing pad, a driving system configured to fold and unfold the foldable support and a control system that controls the driving system to fold and unfold the foldable support and the polishing pad.

### CROSS-REFERENCE TO RELATED APPLICATIONS

This application claims priority to Korean Patent Application No. 10-2024-0046250, filed in the Korean Intellectual Property Office on Apr. 4, 2024, the contents of which are hereby incorporated by reference.

### BACKGROUND

Chemical mechanical polishing (CMP) is a widely used processing technology for the planarization of a semiconductor surface. Because the surface of the polishing pad is worn out or its lifespan is reduced as the chemical mechanical polishing by the polishing pad continues, the polishing pad should be replaced periodically.

Manually replacing the polishing pad of the chemical mechanical polishing device can result in problems such as bubbles being generated between the polishing pad and the platen due to lack of skill of the worker, exposure of the worker to slurry residues, and so on. In addition, it also requires periodic maintenance and repair work, which increases the cost of semiconductor production and decreases productivity. Although the polishing pad replacement work may be automated, considering the size of the polishing pad, it is difficult to ensure enough space for the automatic replacement process of the polishing pad. Accordingly, there is a need for a device that can automatically replace the polishing pad, while solving the problems described above.

### SUMMARY

In general, in some aspects, the present disclosure is directed toward an automatic polishing pad replacement device and a polishing device including the same.

According to some implementation, the present disclosure is directed to an automatic polishing pad replacement device that includes a foldable support configured to support a polishing pad, a driving system configured to fold and unfold the foldable support and a control system configured to control the foldable support and the driving system, wherein the control system is configured to control the driving system to fold and unfold the polishing pad and the foldable support.

According to some implementations, the present disclosure is directed to a polishing device that includes a rotatable platen, a conditioner for polishing a surface of a polishing pad, a slurry supply system configured to supply a slurry to the polishing pad, a polishing head that presses a substrate against the polishing pad and rotates the polishing pad, an automatic polishing pad replacement device configured to automatically replaces the polishing pad and a control system configured to control operations of the platen, the conditioner, the slurry supply system, the polishing head, and the automatic polishing pad replacement device, wherein the automatic polishing pad replacement device may include a foldable support configured to support the polishing pad and a driving system configured to fold and unfold the foldable support, and the control system is configured to control the driving system to fold and unfold the polishing pad and the foldable support.

According to some implementations, the present disclosure is directed to an automatic polishing pad replacement device that includes a polishing pad including a plurality of pads that are at least partially separated from each other, a foldable support configured to support the polishing pad, a driving system configured to fold and unfold the foldable support and a control system configured to control the foldable support and the driving system, wherein the foldable support may include a plurality of supports configured to support the plurality of pads, respectively, and the control system is configured to control the driving system to: fix the polishing pad attached to a platen to the foldable support, fold the polishing pad and the foldable support, move the folded polishing pad and the folded foldable support in a direction away from the platen and unfold the folded polishing pad and the folded foldable support.

According to some implementations, by folding the foldable support before moving the foldable support, the space required for automatic replacement of the polishing pad can be reduced compared to when the foldable support is moved in an unfolded state.

According to some implementations, by forming a groove for accommodating the protrusion in the outer periphery of the platen, the operation of separating the polishing pad from the platen or attaching the polishing pad to the platen can be easily performed.

According to some implementations, the support arm has a hinge structure, so that the operation of attaching the polishing pad to the platen can be easily performed.

According to some implementations, by accommodating the polishing pad inside the platen at a distance apart from the bottom surface of the platen, it is possible to prevent foreign substances attached to the polishing pad from contaminating the inside of the platen, or prevent foreign substances inside the platen from contaminating the polishing pad.

### BRIEF DESCRIPTION OF THE DRAWINGS

Example implementations will be more clearly understood from the following detailed description, taken in conjunction with the accompanying drawings.

FIG. 1 schematically illustrates an example of a chemical mechanical polishing device according to some implementations.

FIG. 2 schematically illustrates an example of a polishing device performing a polishing process of a semiconductor substrate according to some implementations.

FIG. 3 illustrates an example of an operation of a polishing pad replacement device separating the polishing pad from the platens according to some implementations.

FIG. 4 illustrates an example of an operation in which the polishing pad replacement device attaches a polishing pad to the platens according to some implementations.

FIG. 5 illustrates an example of platens formed with a groove for accommodating a protruding part of the support arm according to some implementations.

FIG. 6 illustrates an example of an automatic polishing pad replacement device that includes a support arm including a hinge structure according to some implementations.

FIG. 7 illustrates an example of an automatic polishing pad replacement device including the vacuum adsorption system that adsorbs a polishing pad by vacuum pressure according to some implementations.

FIG. 8 illustrates an example of a driving system for folding or unfolding a foldable support and a polishing pad according to some implementations.

FIG. 9 illustrates an example in which a foldable support is folded with respect to one central axis by a driving system according to some implementations.

FIG. 10 illustrates an example in which a foldable support is folded with respect to a plurality of central axes according to some implementations.

FIG. 11 illustrates an example of a foldable support for folding and unfolding a polishing pad including a plurality of pads according to some implementations.

FIG. 12 illustrates an example in which the foldable support is folded with respect to the central portion of the foldable support according to some implementations.

FIG. 13 illustrates an example of a foldable support for folding and unfolding a polishing pad including a plurality of pads according to some implementations.

FIG. 14 illustrates an example in which each of a plurality of supports of a foldable support is folded with respect to at least one cutting line according to some implementations.

FIG. 15 illustrates an example of a foldable support fixed to a platen according to some implementations.

FIG. 16 is a flowchart illustrating an example of a method for separating a polishing pad according to some implementations.

FIG. 17 is a flowchart illustrating an example of a method for attaching a polishing pad according to some implementations.

FIG. 18 is a flowchart illustrating an example of a method for flipping a polishing pad according to some implementations.

### DETAILED DESCRIPTION

Hereinafter, example implementations will be explained in detail with reference to the accompanying drawings. In the present disclosure, “controlling A” may be used interchangeably with “controlling a driving system that drives A”.

In the present disclosure, a “folding part” may refer to a component or part of a specific object, which is designed to bend or fold the object. For example, the “folding part” may include a hinge (one-axis hinge or multi-axis hinge of two or more axes), a joint, a crease, a bellows structure, a fluid injection chamber, etc. designed to bend or fold the specific object.

In the present disclosure, when A and B are “at least partially separated”, it may refer to a state in which A and B are completely separated from each other, or in which a border between A and B is partially cut but not completely separated from each other, or in which a groove is formed in the border between A and B allowing A and B to easily fold along the border.

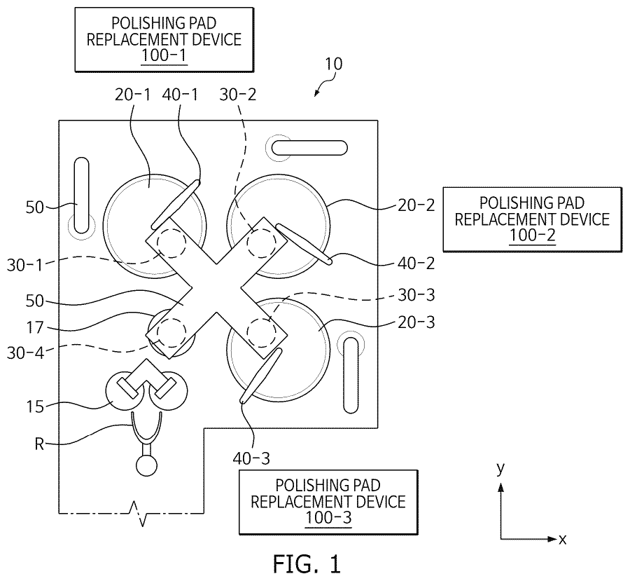

Hereinafter, various aspects of the present disclosure will be described with reference to FIGS. 1 to 18. The same reference numerals may refer to the same components throughout the description.

FIG. 1 schematically illustrates an example of a chemical mechanical polishing device according to some implementations. In FIG. 1, a chemical mechanical polishing device 10 may include first to third platens 20-1, 20-2, and 20-3, first to fourth polishing heads 30-1, 30-2, 30-3, and 30-4, and first to third slurry supply systems 40-1, 40-2, and 40-3. The chemical mechanical polishing device 10 may further include a multi-head carousel 36, first to third conditioners 50, a semiconductor substrate inversion system 15, a load and unload system 17, and a robot R.

Polishing pads may be mounted on the first to third platens 20-1, 20-2, and 20-3, respectively. The first to third polishing heads 30-1, 30-2, and 30-3 and the first to third slurry supply systems 40-1, 40-2, and 40-3 may be disposed on the first to third platens 20-1, 20-2, and 20-3, respectively.

The first to fourth polishing heads 30-1, 30-2, 30-3, and 30-4 may be attached to the multi-head carousel 36 which is rotatable, and moved onto the first to third platens 20-1, 20-2, and 20-3 and the load and unload system 17. The first to fourth polishing heads 30-1, 30-2, 30-3, and 30-4 may be configured to be capable of an elevating operation and a rotating operation independently. The semiconductor substrate inversion system 15 may invert and transfer the semiconductor substrate to the load and unload system 17 for polishing, or may invert and take out the semiconductor substrate from the load and unload system 17. The robot R may transfer the semiconductor substrate to be polished to the semiconductor substrate inversion system 15, or may take the polished semiconductor substrate out of the semiconductor substrate inversion system 15. The first to third conditioners 50-1, 50-2, and 50-3 may adjust the state of the polishing pads so as to maintain a constant polishing rate.

The chemical mechanical polishing device 10 may further include first to third polishing pad replacement devices 100-1, 100-2, and 100-3. The first to third polishing pad replacement devices 100-1, 100-2, and 100-3 may separate the polishing pads (e.g., used polishing pads) attached to the first to third platens 20-1, 20-2, and 20-3 from the platens, or attach the polishing pads (e.g., polishing pads to be used) to the first to third platens 20-1, 20-2, and 20-3, respectively.

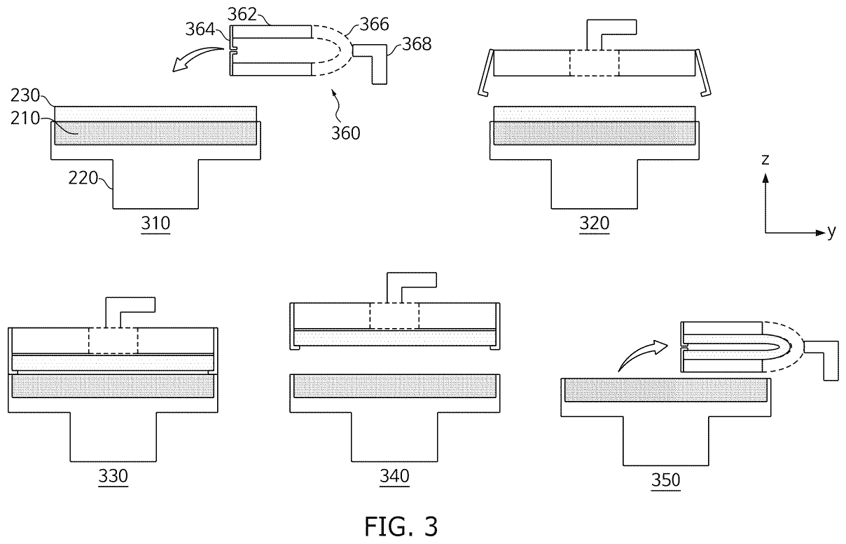

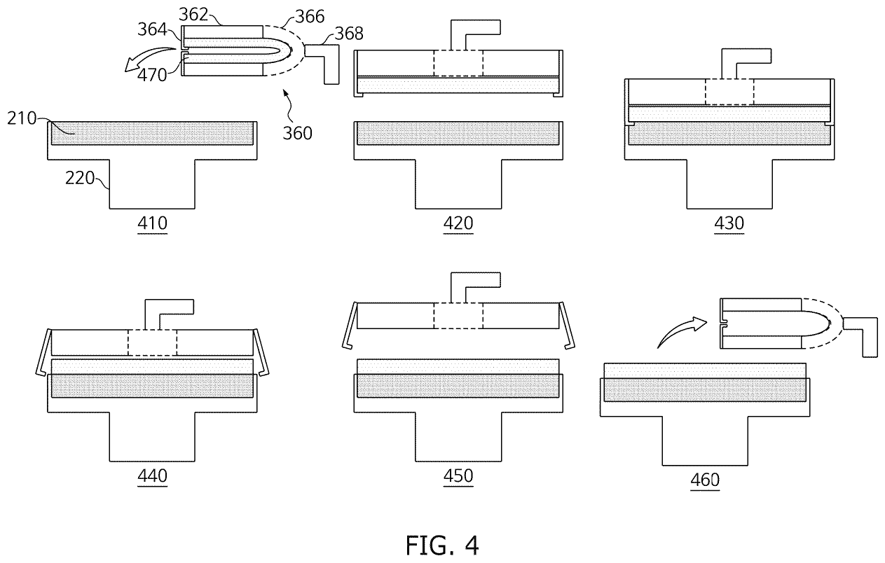

It is illustrated the first to third polishing pad replacement devices 100-1, 100-2, and 100-3 are located on the sides of the first to third platens 20-1, 20-2, and 20-3, but this is for convenience of explanation and the present disclosure is not limited thereto. For example, the first to third polishing pad replacement devices 100-1, 100-2, and 100-3 may be located on the sides, upper sides (in +z direction), etc. of the first to third platens 20-1, 20-2, and 20-3 depending on the progress of the polishing pad replacement process using the first to third polishing pad replacement devices 100-1, 100-2, and 100-3. An example of the polishing pad replacement process using any one of the first to third polishing pad replacement devices 100-1, 100-2, and 100-3 will be described below in detail with reference to FIGS. 3 and 4.

FIG. 1 illustrates an example of the chemical mechanical polishing device 10 that includes several platens and several polishing pad replacement devices, and the arrangement of the platens and polishing pad replacement devices are not limited to the example illustrated in FIG. 1. For example, several platens and polishing pad replacement devices may be arranged linearly.

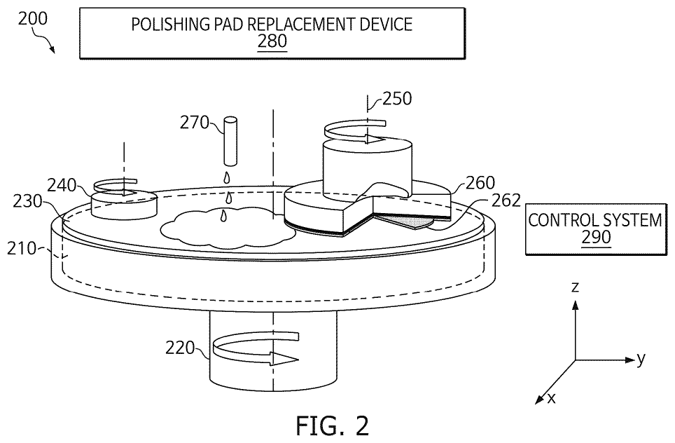

FIG. 2 schematically illustrates an example of a polishing device 200 performing a polishing process of a semiconductor substrate according to some implementations. Platens 210 and 220 of FIG. 2 may be any of the first to third platens 20-1, 20-2, and 20-3 of FIG. 1, and a polishing pad replacement device 280 of FIG. 2 may be any of the first to third polishing pad replacement devices 100-1, 100-2, and 100-3 illustrated in FIG. 1.

The platens 210 and 220 may include a first platen 210 and a second platen 220 supporting the first platen 210. A polishing pad 230 that provides a place where a semiconductor substrate 262, such as a wafer, is chemically and mechanically polished may be in direct contact with (e.g., attached to an upper surface of) the first platen 210. A rotating axis may be connected to the second platen 220 such that the second platen 220 may be rotated by a driving device, such as a motor. As the second platen 220 is rotated, the first platen 210 and the polishing pad 230 may also be rotated together (e.g., at the same angular speed as the second platen 220).

A conditioner 240, a polishing head 260, and a slurry supply system 270 may be disposed on the platens 210 and 220 of the polishing device 200. The conditioner 240 may polish the surface of the polishing pad and adjust the state of the polishing pad 230 so as to maintain a constant polishing rate.

The semiconductor substrate 262 to be chemically and mechanically polished may be attached below the polishing head 260 by vacuum. For example, the polishing head 260 may press the semiconductor substrate 262 against the polishing pad 230 at a constant pressure, while rotating about a rotation axis 250 to chemically and mechanically polish the semiconductor substrate 262. A layer to be polished may be formed on the semiconductor substrate 262, and this layer to be polished may be a silicon oxide layer, a metal layer, etc.

The slurry supply system 270 may be spaced apart from the polishing head 260. The slurry supply system 270 may supply (e.g., spray) the slurry to the polishing pad 230. The slurry sprayed from the slurry supply system 270 may be used for the mechanical polishing of the surface of the layer to be polished and discharged to the outside of the platens 210 and 220.

The polishing pad replacement device 280 may automatically replace the polishing pad 230. A specific process of the polishing pad replacement device 280 replacing the polishing pad 230 will be described below in detail with reference to FIGS. 3 and 4.

In order for the polishing pad replacement device 280 to replace the polishing pad 230, the conditioner 240, the polishing head 260, and the slurry supply system 270 on the platen 220 may be moved in advance in an upward direction (+z direction) of the platen 220, a direction away from the platen 220 (moved on xy plane), or in a direction combining the same.

Operations of the platens 210 and 220, the conditioner 240, the polishing head 260, the slurry supply system 270, and/or the polishing pad replacement device 280 may be controlled by a control system 290. For example, the polishing pad replacement device 280 may include a foldable support that supports the polishing pad 230, and a driving system, and the control system 290 may control the operations, etc. of the foldable support and the driving system. The driving system controlled by the control system 290 may include any driving system included in the platens 210 and 220, the conditioner 240, the polishing head 260, the slurry supply system 270, and the polishing pad replacement device 280. For example, the driving system may include a driving system that folds and/or unfolds the foldable support, a driving system that transfers the foldable support, a driving system that moves a support arm of the foldable support, etc.

FIG. 3 illustrates an example of an operation of a polishing pad replacement device 360 separating the polishing pad 230 from the platens 210 and 220 according to some implementations. The polishing pad 230 may be a used polishing pad that requires replacement.

The operation of the polishing pad replacement device 360 separating the polishing pad 230 from the platens 210 and 220 may be controlled by a control system (e.g., the control system 290 of FIG. 2). The polishing pad replacement device 360 of FIG. 3 may correspond to the polishing pad replacement device 280 of FIG. 2.

The polishing pad replacement device 360 may include a foldable support that supports the polishing pad 230, and a driving system 368. The foldable support may include a support body 362, one or more support arms 364, and a folding part 366. The folding part 366 may allow the foldable support to be folded and/or unfolded with respect to at least one central axis. The driving system 368 may fold and/or unfold the foldable support with respect to at least one central axis. In addition, the driving system 368 may transfer the foldable support.

A first operation 310 represents an example in which the foldable support is moved to above the platens 210 and 220 attached with the polishing pad 230. The foldable support may be folded before being moved to above the platens 210 and 220. Accordingly, the space required for automatic replacement of the polishing pad may be reduced compared to when the foldable support is moved in the unfolded state.

A second operation 320 represents an example in which the folded foldable support is unfolded above the platens 210 and 220. The unfolded foldable support may be moved in a direction (-z direction) closer to the platens 210 and 220. The one or more support arms 364 may be in a state of being rotated outward from the support body 362.

A third operation 330 represents an example in which the polishing pad 230 attached to the platens 210 and 220 is fixed to the foldable support. For example, the foldable support may support the polishing pad 230 with the support body 362 supporting an upper part of the polishing pad 230, and the one or more support arms 364 supporting at least a portion of a lower part of the polishing pad 230.

A fourth operation 340 represents an example in which the polishing pad 230 is fixed to the foldable support and then the foldable support is moved in the upper direction (+z direction) of the platens 210 and 220 such that the polishing pad 230 is separated from the platens 210 and 220.

A fifth operation 350 represents an example in which the polishing pad 230 and the foldable support are folded together above the platens 210 and 220, and moved in a direction away from the platens 210 and 220. The folded polishing pad 230 and the foldable support may be moved in the direction away from the platens 210 and 220 and then unfolded outside the platens 210 and 220, and the polishing pad 230 may be separated from the foldable support.

FIG. 4 illustrates an example of an operation in which the polishing pad replacement device 360 attaches a polishing pad 470 to the platens 210 and 220 according to some implementations. The polishing pad 470 may be a new polishing pad that is not used. The operation of the polishing pad replacement device 360 attaching the polishing pad 470 to the platens 210 and 220 may be controlled by a control system (e.g., the control system 290 of FIG. 2).

A first operation 410 represents an example in which the polishing pad 470 and a foldable support are moved to above the platen. The polishing pad 470 and the foldable support may be moved to above the platen together in a folded state. The polishing pad 470 may be in a state of being fixed to the foldable support using one or more support arms 364. The location at which the foldable support is folded and a folding degree thereof may be set such that the polishing pad 470 does not deform.

A second operation 420 represents an example in which the folded polishing pad 470 and the foldable support are unfolded above the platen. The unfolded foldable support may be moved in a direction (−z direction) closer to the platens 210 and 220.

A third operation 430 represents an example in which the polishing pad 470 is in direct contact with the platens 210 and 220. By the direct contact of the polishing pad 470 with the platens 210 and 220, the polishing pad 470 may be attached to the platens 210 and 220. For example, the polishing pad 470 may be attached to an upper surface of the first platen 210 using an adhesive layer (not illustrated).

A fourth operation 440 represents an example in which the polishing pad 470 is separated from the foldable support by a rotation of one or more support arms 364. A fifth operation 450 represents an example in which the foldable support is transferred upward from the platens 210 and 220.

A sixth operation 460 represents an example in which the foldable support is folded above the platens 210 and 220 and then moved in a direction away from the platens 210 and 220.

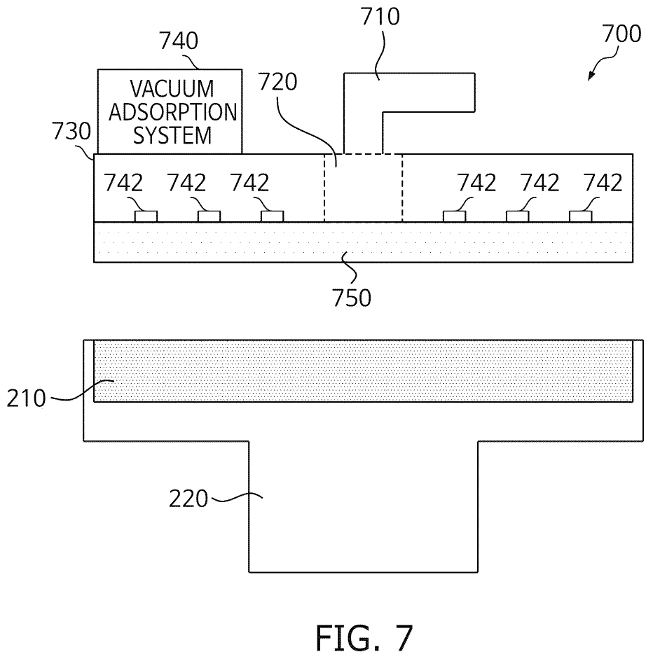

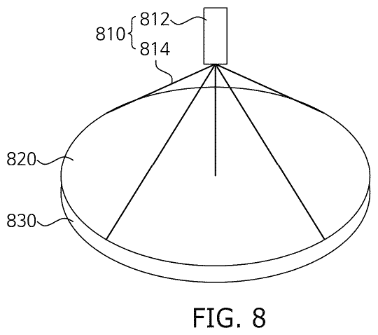

The shapes of the folded foldable support and polishing pad illustrated in FIGS. 3 and 4 are for convenience of description and the present disclosure is not limited thereto. For example, the foldable support and the polishing pad may be folded according to any one of the examples to be described in FIGS. 8 to 14. In addition, FIGS. 3 and 4 illustrate that the polishing pad is fixed to the foldable support using the support arms 364, but the present disclosure is not limited thereto. Additionally, or in some implementations, the polishing pad may be fixed to the foldable support by a vacuum adsorption system 740 of FIG. 7.

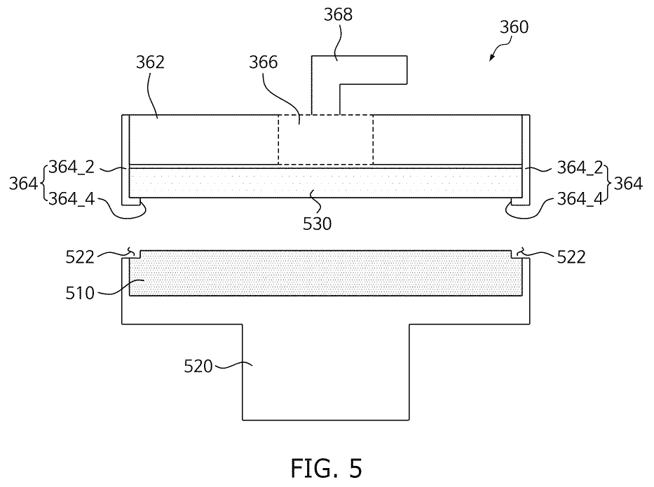

FIG. 5 illustrates an example of platens 510 and 520 formed with a groove 522 for accommodating a protruding part 364_2 of the support arm 364 according to some implementations. The one or more support arms 364 may include a side support part 362_2 that supports a side of a polishing pad 530, and a protruding part 364_4 that extends from the side support part 364_2 and supports at least a portion of a lower part of the polishing pad 530. The protruding part 364_4 may be formed to vertically extend from the side support part 364_2.

The groove 522 that accommodates the protruding part 364_4 may be formed in an outer periphery of the platens 510 and 520. For example, the groove 522 may be formed in a circular shape along the outer periphery of the platens 510 and 520. In some implementations, the groove 522 may include a plurality of grooves formed in the outer periphery of the platens 510 and 520 to accommodate a plurality of protruding parts 364_4.

By forming the groove 522 for accommodating the protruding part 362_4 in the outer periphery of the platens 510 and 520, the operation of separating the polishing pad 530 from the platens 510 and 520 or attaching the polishing pad 530 to the platens 510 and 520 may be easily performed. For example, when separating the polishing pad 530 attached to the platens 510 and 520, the space for the protruding part 364_4 to enter the lower part of the polishing pad 530 is ensured such that the protruding part 362_4 may support the lower part of the polishing pad 530 more easily. Likewise, when attaching the polishing pad 530 to the platens 510 and 520, the space for the protruding part 364_4 to exit after the polishing pad 530 contacts the platens 510 and 520 is ensured such that the polishing pad 530 may be attached easily.

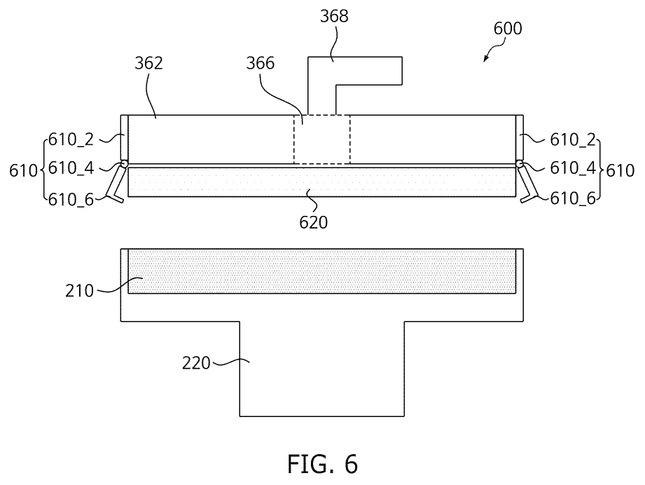

FIG. 6 illustrates an example of an automatic polishing pad replacement device 600 that includes a support arm 610 including a hinge structure 610_4 according to some implementations. The support arm 610 may include a first arm 610_2 connected to the support body 362, a second arm 610_6 connected to the first arm 610_2, and a hinge structure 610_4. The second arm 610 6 may include a protruding part that supports at least a portion of a lower part of a polishing pad 620. The hinge structure 610_4 may be disposed between the first arm 610_2 and the second arm 610 6 such that the second arm 610_6 is rotatable about the hinge structure 610_4.

The polishing pad 620 may be separated from the foldable support by a rotation of the second arm 610_6. Accordingly, an operation of attaching the polishing pad 620 to the platens 210 and 220 may be easily performed. For example, before the polishing pad 620 is attached to the platens 210 and 220, the second arm 610_6 may be rotated ourwardly in advance to separating the polishing pad 620 from the foldable support, so that the entire lower part of the polishing pad 620 may be attached in close contact with the platens 210 and 220 without having a stepped portion that may be formed due to the protruding part of the second arm 610_6.

FIG. 7 illustrates an example of an automatic polishing pad replacement device 700 including the vacuum adsorption system 740 that adsorbs (fixes) a polishing pad 750 by vacuum pressure according to some implementations. The automatic polishing pad replacement device 700 may include a driving system 710, a folding part 720, a foldable support 730, and the vacuum adsorption system 740.

The foldable support 730 may include one or more vacuum adsorption holes 742. Each of the one or more vacuum adsorption holes 742 may be connected to the vacuum adsorption system 740 through a connection pipe (not illustrated). The vacuum adsorption system 740 may be controlled such that the vacuum pressure generated from the vacuum adsorption system 740 may be transferred to the one or more vacuum adsorption holes 742 through the connection pipe, and the polishing pad 750 is adsorbed to the foldable support 730 by the vacuum pressure from the one or more vacuum adsorption holes 742. For example, a plurality of valves (e.g., throttle valves) capable of switching on and off suction of air may be placed between the vacuum adsorption system 740 and a plurality of connection pipes.

The air suction may be performed simultaneously in the one or more vacuum adsorption holes 742. In some implementations, the air suction using each of the one or more vacuum adsorption holes 742 may be individually performed. For example, a control system (e.g., the control system 290 in FIG. 2) may individually control a plurality of valves, and by switching on and off a plurality of valves while the vacuum adsorption system 740 is driven, may individually allow the air suction to be performed using each of the one or more vacuum adsorption holes 742.

A structure for adsorbing the polishing pad 750 to the foldable support 730 using the vacuum adsorption system 740 may be used together with a structure for supporting the polishing pad using the support arm of the foldable support. For example, the one or more support arms 364 of FIG. 3 or the support arm 610 of FIG. 6 and the vacuum adsorption system 740 may be used together.

The number of the one or more vacuum adsorption holes 742 and/or the vacuum pressure from the one or more vacuum adsorption holes 742 may vary depending on the size of the foldable support, the size, weight, etc. of the polishing pad 750, etc.

FIG. 8 illustrates an example of a driving system 810 for folding or unfolding a foldable support 820 and a polishing pad 830 according to some implementations. The driving system 810 may include a driving system main body 812 and a plurality of rods 814. The plurality of rods 814 may be connected to the driving system main body 812 and the foldable support 820.

The driving system 810 may use the plurality of rods 814 to fold and/or unfold the foldable support 820 with respect to at least one central axis. As the foldable support 820 is folded or unfolded, the polishing pad 830 fixed to the foldable support 820 (e.g., fixed by the support arm and/or the vacuum adsorption system) may also be folded or unfolded.

The foldable support 820 may further include a folding part (not illustrated) that allows the foldable support 820 to be folded and/or unfolded with respect to at least one central axis.

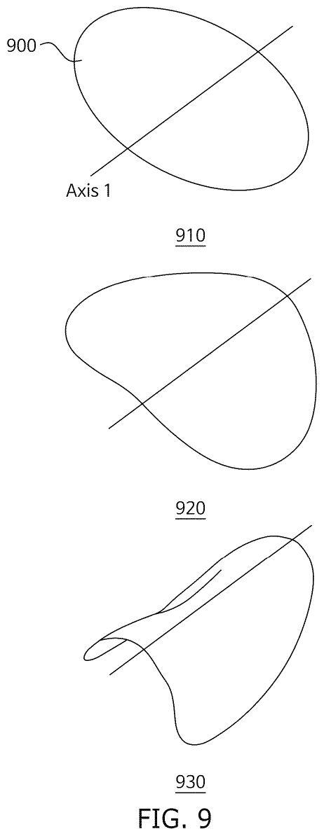

FIG. 9 illustrates an example in which a foldable support 900 is folded with respect to one central axis (e.g., Axis 1) by a driving system according to some implementations. A first operation 910 represents an example before the foldable support 900 is folded (e.g., in an unfolded state). For example, the foldable support 900 before being folded may have a flat disk shape.

A second operation 920 represents an example in which the foldable support 900 is partially folded with respect to one central axis (e.g., Axis 1).

A third operation 930 represents an example in which the foldable support 900 is folded with respect to one central axis (e.g., Axis 1). Accordingly, the space required for automatic replacement of the polishing pad may be reduced.

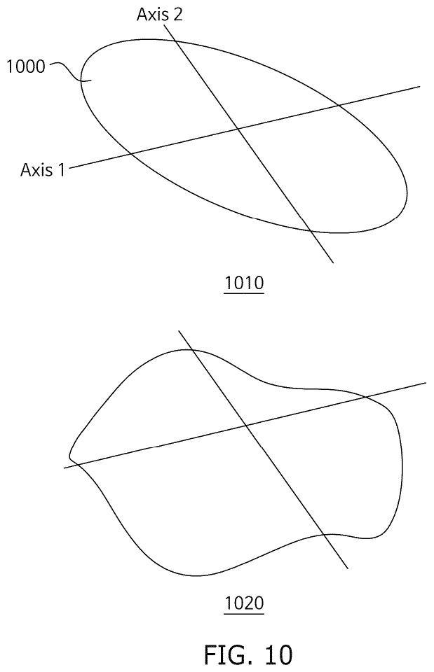

FIG. 10 illustrates an example in which a foldable support 1000 is folded with respect to a plurality of central axes (e.g., Axis 1, Axis 2) according to some implementations. A first operation 1010 represents an example before the foldable support 1000 is folded (e.g., in an unfolded state).

A second operation 1020 represents an example in which the foldable support 1000 is partially folded with respect to a plurality of central axes (e.g., Axis 1, Axis 2). After the second operation 1020, the foldable support 1000 may be further folded with respect to a plurality of central axes (e.g., Axis 1, Axis 2).

FIG. 10 illustrates that the foldable support 1000 is folded with respect to two central axes, but the present disclosure is not limited thereto, and the foldable support 1000 may be folded with respect to three or more central axes. Accordingly, the space required for automatic replacement of the polishing pad may be reduced.

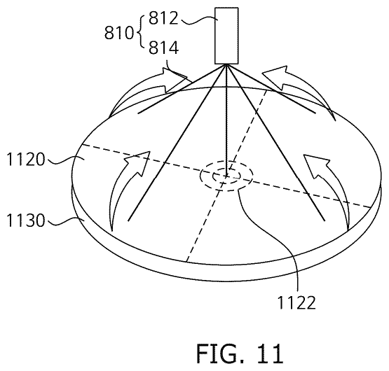

FIG. 11 illustrates an example of a foldable support 1120 for folding or unfolding a polishing pad 1130 including a plurality of pads according to some implementations. The polishing pad 1130 may include a plurality of pads that are at least partially separated from each other. For example, the polishing pad 1130 may have shallow cuts or indentations between the plurality of pads, facilitating easier folding. The foldable support 1120 may include a plurality of supports that support a plurality of pads, respectively. The plurality of supports may be at least partially separated from each other.

For example, FIG. 11 illustrates that the polishing pad 1130 includes four pads at least partially separated from each other, and the foldable support 1120 includes four supports that support the four pads, respectively. The present disclosure is not limited thereto, and the polishing pad 1130 may include any number of pads, and the foldable support 1120 may include any number of supports.

The foldable support 1120 may include a central folding part 1122 that allows a plurality of supports to be folded and/or unfolded with respect to a central portion of the foldable support 1120.

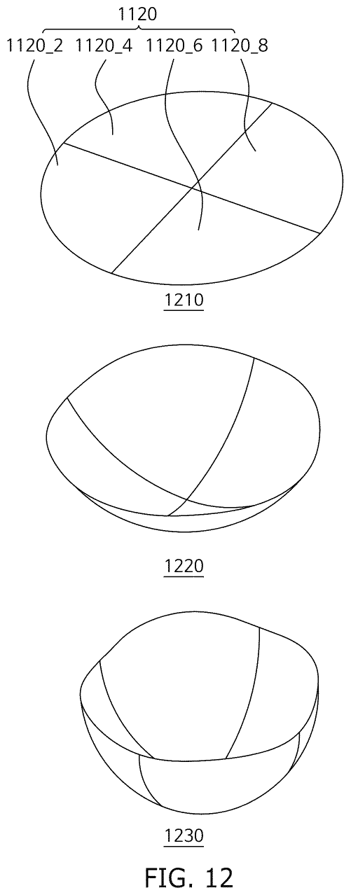

FIG. 12 illustrates an example in which the foldable support 1120 is folded with respect to the central portion of the foldable support 1120 according to some implementations. The foldable support 1120 may include first to fourth supports 1120_2, 1120_4, 1120_6, and 1120_8.

A first operation 1210 represents an example before the foldable support 1120 is folded (e.g., in an unfolded state). For example, the foldable support 1120 before being folded may have a flat disk shape.

A second operation 1220 represents an example in which the foldable support 1120 is partially folded with respect to the central portion of the foldable support 1120.

A third operation 1230 represents an example in which the foldable support 1120 is further folded with respect to the central portion of the foldable support 1120. Accordingly, the space required for automatic replacement of the polishing pad may be reduced.

In the second operation 1220 and the third operation 1230, due to a structure in which the first to fourth supports 1120_2, 1120_4, 1120_6, and 1120_8 are at least partially separated from each other, the first to fourth supports 1120_2, 1120_4, 1120_6, and 1120_8 may be folded to overlap each other by at least a portion of their areas. Accordingly, a space occupied by the folded foldable support 1120 may be further reduced.

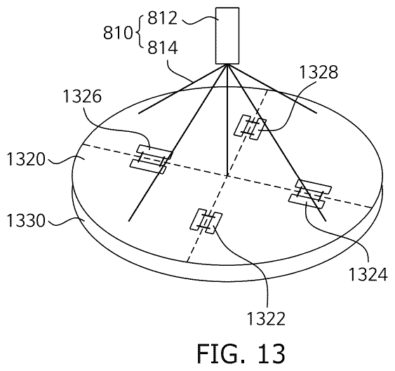

FIG. 13 illustrates another example of a foldable support 1320 for folding or unfolding a polishing pad 1330 including a plurality of pads according to some implementations. The polishing pad 1330 may include a plurality of pads that are at least partially separated from each other. For example, the polishing pad 1330 may have shallow cuts or indentations between the plurality of pads, facilitating easier folding. The foldable support 1320 may include a plurality of supports that support a plurality of pads, respectively. The plurality of supports may be at least partially separated from each other.

For example, the polishing pad 1330 may include four pads at least partially separated from each other, and the foldable support 1320 includes four supports that support the four pads, respectively. The present disclosure is not limited thereto, and the polishing pad 1330 may include any number of pads, and the foldable support 1320 may include any number of supports.

The foldable support 1320 may include folding parts 1322, 1324, 1326, and 1328 disposed at locations corresponding to at least one cutting line such that each of the plurality of supports is folded with respect to the at least one cutting line.

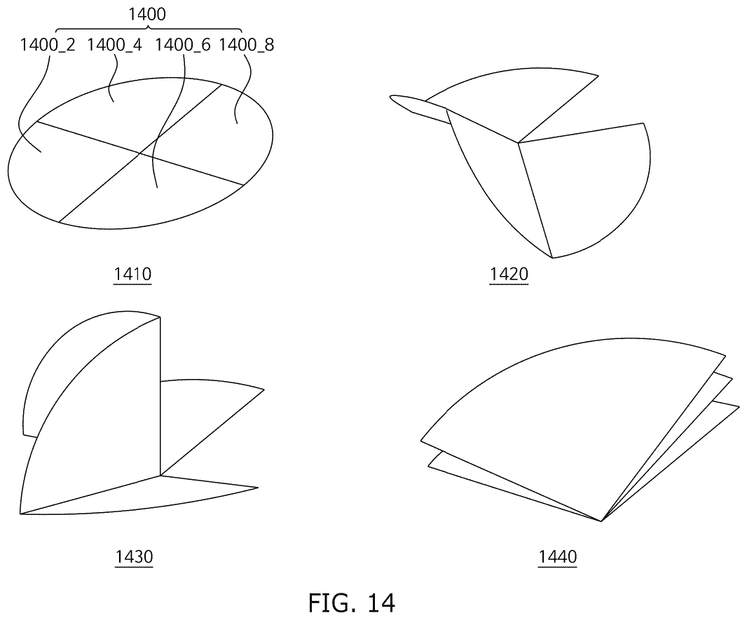

FIG. 14 illustrates an example in which each of a plurality of supports 1400_2, 1400_4, 1400_6, and 1400_8 of a foldable support 1400 is folded with respect to at least one cutting line according to some implementations. A first operation 1410 represents an example before the foldable support 1400 is folded (e.g., in an unfolded state). For example, the foldable support 1400 before being folded may have a flat disk shape.

A second operation 1420 represents an example in which each of the plurality of supports 1400_2, 1400_4, 1400_6, and 1400_8 is partially folded with respect to at least one cutting line. For example, the first support 1400_2 and the third support 1400_6 may be folded in a direction in which the first support 1400_2 and the second support 1400_4 are folded, and in a direction opposite to a direction in which the third support 1400_6 and the fourth support 1400_8 are folded.

A third operation 1430 represents an example in which the foldable support 1400 is further folded in the direction in which each of the plurality of supports 1400_2, 1400_4, 1400_6, and 1400 8 is folded in the second operation 1420.

A fourth operation 1440 represents an example in which the foldable support 1400 is folded such that the plurality of supports 1400_2, 1400_4, 1400_6, and 1400_8 overlap with each other. Accordingly, the space required for automatic replacement of the polishing pad may be reduced.

In FIGS. 9, 10, 12, and 14, illustrations of a driving system, a folding part, etc. for folding the foldable support are omitted for convenience of description. In addition, in FIGS. 9, 10, 12, and 14, the illustration of the polishing pad fixed to the foldable support may be omitted. In each drawing, the foldable support and the polishing pad may be folded in a form similar to that illustrated in each drawing in a state in which the polishing pad is fixed to the foldable support. In each drawing, unfolding of the foldable support may be performed in the reverse order of the operations illustrated and described.

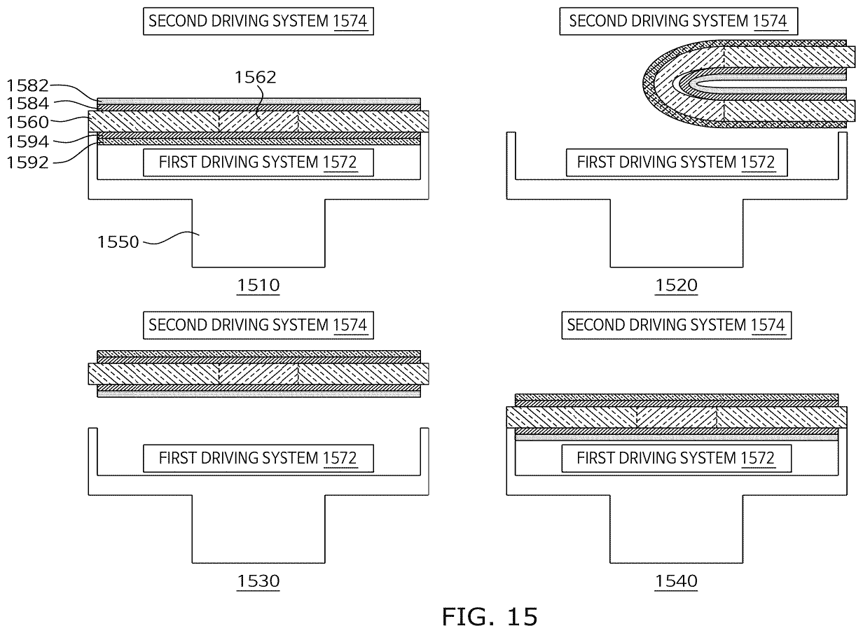

FIG. 15 illustrates an example of a foldable support 1560 fixed to a platen 1550 according to some implementations. The platen 1550 and the foldable support 1560 may be rotated together, and the chemical mechanical polishing may be performed by polishing pads 1582 and 1592 attached to the foldable support 1560. That is, the foldable support 1560 may serve as a part of the platen (e.g., the first platen 210 of FIG. 2).

The polishing pads 1582 and 1592 attached to the foldable support 1560 may include a first polishing pad 1582 and a second polishing pad 1592. The first polishing pad 1582 may be attached to a first surface of the foldable support 1560, and the second polishing pad 1592 may be attached to a second surface opposite the first surface attached with the first polishing pad 1582.

A first adhesive layer 1584 may be disposed between the first polishing pad 1582 and the first surface of the foldable support 1560, so that the first polishing pad 1582 may be fixed and attached to the first surface of the foldable support 1560. Likewise, a second adhesive layer 1594 may be disposed between the second polishing pad 1592 and the second surface of the foldable support 1560, so that the second polishing pad 1592 may be fixed and attached to the second surface of the foldable support 1560. Additionally, or in some implementations, the first polishing pad 1582 and the second polishing pad 1592 may be fixed to the foldable support 1560 by a support arm (e.g., 364 in FIG. 3) and/or a vacuum adsorption system (e.g., 740 in FIG. 7).

In FIG. 15, the second polishing pad 1592 may be accommodated inside the platen 1550 while being spaced apart from a bottom surface of the platen 1550. Because the second polishing pad 1592 is accommodated at a distance from the bottom surface of the platen 1550, if the second polishing pad 1592 is a used pad that needs to be replaced, it is possible to prevent foreign substances attached to the second polishing pad 1592 from contaminating the interior of the platen 1550 during polishing. Conversely, if the second polishing pad 1592 is a new polishing pad that is not used, it is also possible to prevent foreign substances inside the platen 1550 from contaminating the second polishing pad 1592.

Operations 1510, 1520, 1530, and 1540 illustrated in FIG. 15 may represent operations of flipping the foldable support 1560. A control system (e.g., the control system 290 of FIG. 2) may control driving systems 1572 and 1574 to flip the foldable support 1560. In an example, the driving systems 1572 and 1574 may include a first driving system 1572 located inside the platen 1550 and a second driving system 1574 located outside the platen 1550. If the first polishing pad 1582 is completely used and needs to be replaced, the foldable support 1560 may be flipped so that it is possible to use the new the second polishing pad 1592 that is not used in chemical mechanical polishing.

A first operation 1510 represents an example in which the foldable support 1560 is fixed onto the platen 1550 before the foldable support 1560 is folded (e.g., in an unfolded state). The first operation 1510 may represent a state of the first polishing pad 1582 being used in the polishing process or a state of the first polishing pad 1582 after being used.

A second operation 1520 represents an example in which the foldable support 1560 is folded. The foldable support 1560 may be folded using the driving systems 1572 and 1574 (or 3 pin-cylinder of the driving system, etc.). For example, the foldable support 1560 may be folded by the first driving system 1572. The foldable support 1560 may include a folding part 1562 that allows the foldable support 1560 to be folded and/or unfolded with respect to at least one central axis. The shape into which the foldable support 1560 is folded in FIG. 15 is only an example, and the present disclosure is not limited thereto.

The foldable support 1560 may be the foldable support illustrated and described in FIGS. 8 to 14, and may be folded based on the operations illustrated and described in FIGS. 9, 10, 12, and 14. In an example, the foldable support 1560 may be folded and/or unfolded with respect to at least one central axis using a plurality of rods of the driving system. In an example, the first and second polishing pads 1582 and 1592 may include a plurality of pads that are at least partially separated from each other, and the foldable support 1560 may include a plurality of supports that support the plurality of pads, respectively. When a plurality of supports are folded and/or unfolded with respect to the central portion of the foldable support 1560, or when each of the plurality of supports is folded and/or unfolded with respect to at least one cutting line, the foldable support 1560 may be folded and/or unfolded.

A third operation 1530 represents an example in which the foldable support 1560 is unfolded. For example, the foldable support 1560 may be unfolded by the second driving system 1574. The foldable support 1560 may be flipped by being folded in the second operation 1520 and then unfolded in the third operation 1530.

A fourth operation 1540 represents an example in which the flipped foldable support 1560 is moved in a direction closer to the platen 1550 and coupled to the platen 1550. If the platen 1550 and the foldable support 1560 are coupled and fixed, the platen 1550 and the foldable support 1560 are rotated together, and the second polishing pad 1592 may be used in the chemical mechanical polishing.

If the second polishing pad 1592 is completely used and needs to be replaced, the foldable support 1560 may be moved in a direction away from the platen 1550. For example, the foldable support 1560 may be folded in a manner similar to the second operation 1520 and moved in a direction away from the platen 1550.

A foldable support with unused polishing pads attached to both sides may be coupled with the platen 1550. For example, the foldable support attached with unused polishing pads on both sides may be moved to above the platen 1550 in a folded state, unfolded, and coupled to the platen 1550.

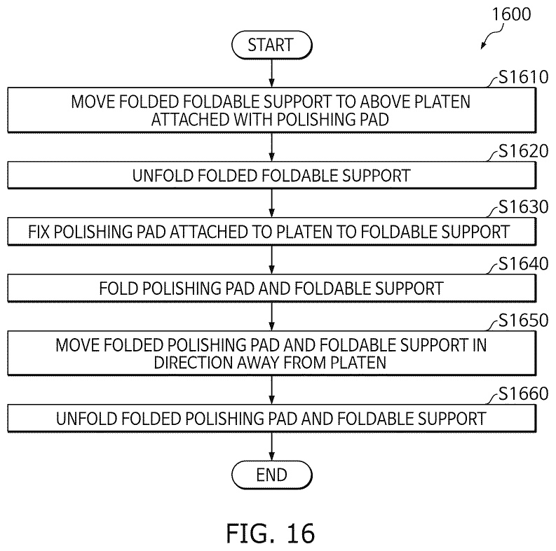

FIG. 16 is a flowchart illustrating an example of a method 1600 for separating a polishing pad according to some implementations. The method 1600 may be performed by a driving system that folds and/or unfolds the foldable support, and a control system that controls the foldable support and the driving system.

The method 1600 may be initiated by moving the folded foldable support to above the platen attached with the polishing pad, at S1610. In some implementations, the foldable support may be moved to above the platen in an unfolded state. The polishing pad attached to the platen may be a polishing pad that is completely used and needs to be replaced.

The driving system may unfold the folded foldable support above the platen, at S1620. The driving system may fix the polishing pad attached to the platen to the foldable support, at S1630. For example, the driving system may move the unfolded foldable support toward the platen and fix the polishing pad attached to the platen to the foldable support. The polishing pad may be fixed to the foldable support by the support arm and/or the vacuum adsorption system of the foldable support.

The driving system may fold the polishing pad and the foldable support, at S1640. The driving system may move the folded polishing pad and the foldable support in a direction away from the platen, at S1650.

After the foldable support is moved in a direction away from the platen, the driving system may unfold the folded polishing pad and foldable support, at S1660. The polishing pad may be separated from the unfolded foldable support.

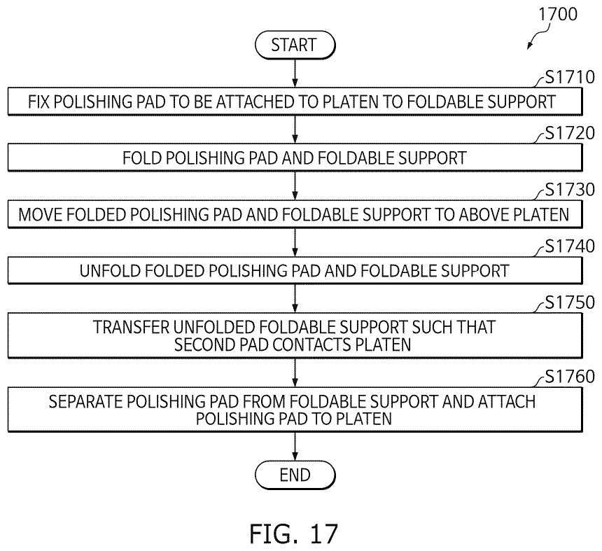

FIG. 17 is a flowchart illustrating an example of a method 1700 for attaching a polishing pad according to some implementations. The method 1700 may be performed by a driving system that folds and/or unfolds the foldable support, and a control system that controls the foldable support and the driving system.

The method 1700 may be initiated by fixing a polishing pad to be attached to the platen to the foldable support (e.g., to the unfolded foldable support), at S1710. In an example, the operation at S1710 may be performed after S1660 of FIG. 16. The polishing pad may be fixed to the foldable support by the support arm and/or the vacuum adsorption system of the foldable support.

The driving system may fold the polishing pad and the foldable support, at S1720. The driving system may move the folded polishing pad and foldable support to above the platen, at S1730.

The driving system may unfold the folded polishing pad and foldable support above the platen, at S1740.

The driving system may transfer the unfolded foldable support such that the second pad contacts the platen, at S1750.

The driving system may separate the polishing pad from the foldable support and attach the same to the platen, at S1760.

The driving system may move the foldable support from which the polishing pad is separated to above the platen, fold the foldable support, and move the folded foldable support in a direction away from the platen.

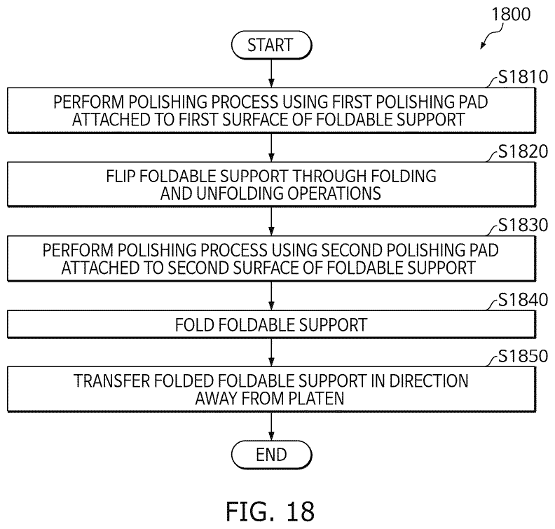

FIG. 18 is a flowchart illustrating an example of a method 1800 for flipping a polishing pad according to some implementations. The method 1800 may be performed by a driving system (e.g., the first driving system and the second driving system) that folds and/or unfolds the foldable support, and a control system that controls the foldable support and the driving system.

The method 1800 may be initiated by performing a polishing process using the first polishing pad attached to the first surface of the foldable support, at S1810. For example, in this state, the first polishing pad may be attached to the first surface of the foldable support, and the second polishing pad may be attached to the second surface opposite the first surface of the foldable support. In addition, the second polishing pad may be accommodated inside the platen while being spaced apart from the bottom surface of the platen. In this case, the foldable support, while being fixed to the platen, may be rotated together with the foldable support, so that chemical mechanical polishing with the first polishing pad may be performed.

In an example, a first adhesive layer may be disposed between the first polishing pad and the first surface of the foldable support such that the first polishing pad may be fixed onto the first surface of the foldable support. In addition, a second adhesive layer is placed between the second polishing pad and the second surface of the foldable support such that the second polishing pad may be fixed onto the second surface of the foldable support.

The driving system may flip the foldable support through the folding and unfolding operation of the foldable support attached with the first polishing pad and the second polishing pad, at S1820. For example, the first driving system located inside the platen may fold the foldable support, and the second driving system located outside the platen may unfold the foldable support. By performing this flip operation when the first polishing pad is completely used and needs to be replaced, the first polishing pad may be accommodated inside the platen, and a new second polishing pad that is not used may be exposed to the outside.

The polishing process may be performed using the second polishing pad attached to the second surface of the foldable support, at S1830.

The driving system may fold the foldable support, at S1840. For example, the first driving system may fold the foldable support when the second polishing pad is completely used and needs to be replaced.

The driving system may transfer the foldable support attached with the first polishing pad and the second polishing pad in a direction away from the platen. For example, the second driving system may move the foldable support in a direction away from the platen.

The driving system may fold a new foldable support attached with new polishing pads on both sides, move the folded new foldable support to above the platen, unfold the folded new foldable support, and couple the unfolded foldable support onto the platen.

The flowcharts illustrated in FIGS. 16 and 18 and examples described above are merely examples, and may be implemented differently. For example, one or more operations in the flowchart may be omitted, the order of operations may be changed, one or more operations may be performed in parallel, or one or more operations may be repeatedly performed multiple times.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An automatic polishing pad replacement device, comprising:
a foldable support configured to support a polishing pad;
a driving system configured to fold and unfold the foldable support; and
a control system configured to control the driving system to fold and unfold the foldable support and the polishing pad.

2. The automatic polishing pad replacement device according to claim 1, further comprising a vacuum adsorption system,
wherein the foldable support comprises one or more vacuum adsorption holes, and
wherein the control is configured to control the vacuum adsorption system to fix the polishing pad to the foldable support by vacuum pressure from the one or more vacuum adsorption holes.

3. The automatic polishing pad replacement device according to claim 1,
wherein the foldable support comprises a support body and one or more support arms, and
wherein the control system is configured to control the one or more support arms to support at least a portion of a lower part of the polishing pad so that the foldable support supports the polishing pad.

4. The automatic polishing pad replacement device according to claim 1,
wherein the driving system comprises a plurality of rods connected to the foldable support, and
wherein the driving system, using the plurality of rods, is configured to fold and unfold the foldable support with respect to at least one central axis.

5. The automatic polishing pad replacement device according to claim 4, wherein the foldable support further comprises a folding part configured to allow the foldable support to be folded and unfolded with respect to the at least one central axis.

6. The automatic polishing pad replacement device according to claim 1,
wherein the polishing pad comprises a plurality of pads that are at least partially separated from each other, and
wherein the foldable support comprises a plurality of supports that support the plurality of pads, respectively.

7. The automatic polishing pad replacement device according to claim 6, wherein the foldable support further comprises a central folding part configured to allow the plurality of supports to be folded and unfolded with respect to a central portion of the foldable support.

8. The automatic polishing pad replacement device according to claim 6, comprising a folding part disposed at a location corresponding to at least one cutting line such that each of the plurality of supports is folded with respect to the at least one cutting line.

9. The automatic polishing pad replacement device according to claim 1, wherein the control system is configured to control the driving system to:
fix the polishing pad to the foldable support, wherein the polishing pad is attached to a platen;
fold the polishing pad and the foldable support;
move the folded polishing pad and the folded foldable support in a direction away from the platen; and
unfold the folded polishing pad and the folded foldable support.

10. The automatic polishing pad replacement device according to claim 1, wherein the control system is configured to control the driving system to:
fix the polishing pad to be attached to a platen to the foldable support;
fold the polishing pad and the foldable support;
move the folded polishing pad and the folded foldable support to above the platen;
unfold the folded polishing pad and the folded foldable support; and
separate the polishing pad from the foldable support so that the polishing pad is attached onto the platen.

11. The automatic polishing pad replacement device according to claim 10,
wherein the foldable support comprises a support body configured to support an upper part of the polishing pad and one or more support arms that support at least a portion of a lower part of the polishing pad,
wherein each of the one or more support arms comprises a first arm connected to the support body, a second arm comprising a protruding part connected to the first arm and configured to support at least a portion of the lower part of the polishing pad, and a hinge structure disposed between the first arm and the second arm configured to allow the second arm to be rotated, and
the control system is configured to control the second arm to be rotated to separate the polishing pad from the foldable support.

12. The automatic polishing pad replacement device according to claim 10,
wherein the foldable support comprises a support body configured to support an upper part of the polishing pad and one or more support arms configured to support at least a portion of a lower part of the polishing pad,
wherein each of the one or more support arms comprises a protruding part configured to support at least a portion of the lower part of the polishing pad, and
wherein a groove is formed in an outer periphery of the platen and configured to accommodate the protruding part therein.

13. The automatic polishing pad replacement device according to claim 1,
wherein the foldable support is fixed to a platen, and
wherein the platen and the foldable support are configured to be rotated together and chemical mechanical polishing is performed by the polishing pad attached to the foldable support.

14. The automatic polishing pad replacement device according to claim 13,
wherein the polishing pad comprises a first polishing pad and a second polishing pad,
wherein the first polishing pad is attached to a first surface of the foldable support,
wherein the second polishing pad is attached to a second surface of the foldable support opposite to the first surface,
wherein the second polishing pad is accommodated inside the platen while being spaced apart from a bottom surface of the platen, and
wherein the first polishing pad is used in the chemical mechanical polishing.

15. The automatic polishing pad replacement device according to claim 14,
wherein a first adhesive layer is disposed between the first polishing pad and the first surface of the foldable support such that the first polishing pad is fixed onto the first surface of the foldable support, and
wherein a second adhesive layer is disposed between the second polishing pad and the second surface of the foldable support such that the second polishing pad is fixed onto the second surface of the foldable support.

16. The automatic polishing pad replacement device according to claim 14,
wherein the control system is configured to control the driving system to fold the foldable support attached with the first polishing pad and the second polishing pad, and unfold the folded foldable support, such that the first polishing pad is accommodated inside the platen, and
wherein the second polishing pad is used in the chemical mechanical polishing.

17. The automatic polishing pad replacement device according to claim 14,
wherein the driving system comprises:
a first driving system located inside the platen; and
a second driving system located outside the platen, and
wherein the control system is configured to control the first driving system to fold the foldable support and control the second driving system to unfold the foldable support, thereby flipping the foldable support.

18. The automatic polishing pad replacement device according to claim 14, wherein the control system is configured to control the driving system to move the foldable support attached with the first polishing pad and the second polishing pad in a direction away from the platen.

19. A polishing device comprising:
a rotatable platen;
a conditioner for polishing a surface of a polishing pad;
a slurry supply system configured to supply a slurry to the polishing pad;
a polishing head configured to press a substrate against the polishing pad and rotate the polishing pad;
an automatic polishing pad replacement device configured to automatically replace the polishing pad; and
a control system configured to control operations of the platen, the conditioner, the slurry supply system, the polishing head, and the automatic polishing pad replacement device,
wherein the automatic polishing pad replacement device comprises a foldable support configured to support the polishing pad and a driving system configured to fold and unfold the foldable support, and
wherein the control system is configured to control the driving system to fold and unfold the polishing pad and the foldable support.

20. An automatic polishing pad replacement device, comprising:
a polishing pad comprising a plurality of pads that are at least partially separated from each other;
a foldable support configured to support the polishing pad;
a driving system configured to fold and unfold the foldable support; and
a control system configured to control the driving system to fold and unfold the foldable support and the polishing pad,
wherein the foldable support comprises a plurality of supports configured to support the plurality of pads, respectively, and
wherein the control system is configured to control the driving system to:
fix the polishing pad attached to a platen to the foldable support;
move the folded polishing pad and the folded foldable support in a direction away from the platen; and
unfold the folded polishing pad and the folded foldable support.
